(19) United States
(12) Patent Application Publication
(10) Pub. No.: US 2020/0166967 A1
(43) Pub. Date: May 28, 2020

(54) Flexible Display for a Mobile Computing Device

(71) Applicant: Queen's University at Kingston, Kingston (CA)

(72) Inventors: Roel Vertegaal, Perth Road (CA); Daniel M. Gotsch, Kingston (CA); Jesse Burstyn, Thornhill (CA)

(21) Appl. No.: 16/588,386

(22) Filed: Sep. 30, 2019

Related U.S. Application Data
(63) Continuation of application No. 15/072,529, filed on Mar. 17, 2016, now abandoned.
(60) Provisional application No. 62/134,268, filed on Mar. 17, 2015.

(51) Int. Cl. G06F 1/16; H01L 27/32; G06F 3/0362; G06F 3/01; H04M 1/02; G06F 3/0488; G02B 30/27

(52) U.S. Cl. CPC G06F 1/1643; H01L 2251/5338; G06F 3/0362; G06F 1/1652; G06F 1/1626; G06F 3/016; G06F 1/1684; H04M 1/0268; G06F 1/1694; G06F 3/04886; G06F 1/1666; G02B 30/27; G06F 2203/04104; G06F 2200/1637; H01L 27/323

(57) ABSTRACT

A display device comprises a flexible display comprising a plurality of pixels and one or more of a z-input element and a flexible array of convex microlenses disposed on the flexible display, wherein each microlens in the array receives light from a selected number of underlying pixels and projects the received light over a range of viewing angles so as to collectively produce a flexible 3D light field display. The display device may be augmented with a flexible x,y-input element. The display device may be implemented in a mobile computing device such as a smartphone, a tablet personal computer, a personal digital assistant, a music player, a gaming device, or a combination thereof. One embodiment relates to a mobile computing device with a flexible 3D display and z-input provided by bending the display.

### RELATED APPLICATION

This application claims the benefit of the filing date of U.S. Patent Application No. 62/134,268, filed on Mar. 17, 2015, the contents of which are incorporated herein by reference in their entirety.

### FIELD

The invention generally relates to flexible displays for mobile computing devices. In particular, the invention relates to interacting with and controlling flexible display devices and mobile computing devices using the display devices. More particularly, the invention relates to flexible 3D display devices and using bending of flexible displays as input for a computing device.

### BACKGROUND

Humans rely heavily on 3D depth cues to locate and manipulate objects and to navigate their surroundings. Among these depth cues are motion parallax—the shift of perspective when a viewer and a viewed object change their relative positions, and stereoscopy—provided by the different lines of sight offered by each of our eyes. Although there has been progress in 3D graphic displays, to date much of the 3D content remains rendered as a 2D image on a flat panel display. Lenticular displays offer limited forms of glasses-free horizontal stereoscopy, with some solutions providing limited, one-dimensional motion parallax. Virtual reality systems, such as the Oculus Rift (Oculus VR, LLC, USA; https://www.oculus.com/ja/rift/) and the Microsoft HoloLens® (Microsoft Corporation, Redmond, USA; https://www.microsoft.com/microsoft-hololens/en-us), require headsets and motion tracking to provide immersive 3D imagery.

Recently there has been renewed interest in 3D displays that do not require 3D glasses, motion tracking, or headsets. Research has focused on designing light field displays that render a 3D scene while preserving all angular information of the light rays. A number of applications have been proposed, such as: teleconferencing, when used with Kinect® (Microsoft Corporation, Redmond, USA)-based input; a 3D display that can both capture and display images; integrating optical sensors at each pixel to record multi-view imagery in real-time; a real-time display that reacts to incident light sources, wherein light sources can be used as input controls; providing 7-DOF object manipulation, when used with a Leap-Motion™ controller (Leap Motion, Inc., San Francisco, USA; https://www.leapmotion.com); and as an input-output device when used with a light pen whose light is captured through the light field display. However, due to their large size and complexity, such applications of light field display systems are only intended for desktop applications, and are not suitable for mobile use.

Interacting with objects in virtual 3D space is a non-trivial task that requires matching physical controllers to translation and rotation of virtual objects. This implies the coordination of control groups—translation, rotation—over several degrees of freedom (DOF). Some previous approaches included separate input devices based on a mouse or a trackball. Another approach involved detecting shifts of objects along the z-axis to minimize contradictions in visual depth cues as the user approached the object in the display. In another approach, 2D interaction techniques were combined with 3D imagery in a single interaction space, although z-axis manipulation was limited only to translation. In another approach, rotate-scale-translate metaphors for 2D manipulation (such as pinch to zoom) were extended into 3D, wherein three or more finger interaction techniques attempted to provide direct manipulation of 3D objects in a multi-touch environment. However, none of the prior approaches is suitable for a mobile device, because they require a separate input device, they require bimanual multi-finger interactions, and/or they sacrifice integrality of control.

### SUMMARY

Described herein is a display device, comprising: a flexible display comprising a plurality of pixels; and a flexible array of convex microlenses disposed on the flexible display; wherein each microlens in the array receives light from a selected number of underlying pixels and projects the received light over a range of viewing angles so as to collectively produce a flexible 3D light field display.

In one embodiment, the display device comprises: an x,y-input element; wherein the x,y-input element senses a user's touch on the display device in the x and y axes and provides corresponding x,y-input information. In one embodiment, the x,y-input element comprises a flexible capacitive multi-touch film. In one embodiment, the flexible capacitive multi-touch film is disposed between the flexible display and the flexible array of convex microlenses

In one embodiment, the display device comprises: at least one z-input element; wherein the at least one z-input element senses a bend of the flexible 3D light field display in the z axis and provides corresponding z-input information. According to an embodiment, one or more properties of a light field rendered on the flexible 3D light field display may be modulated by bending the flexible 3D light field display. In one embodiment, the at least one z-input element comprises a bend sensor.

Also described herein is a display device, comprising: a flexible display comprising a plurality of pixels; and at least one z-input element; wherein the at least one z-input element senses a bend of the flexible display in the z axis and provides corresponding z-input information. According to an embodiment, one or more properties of content rendered on the flexible display may be modulated by bending the flexible display. In one embodiment, the at least one z-input element comprises a bend sensor.

Also described herein is a mobile computing device, comprising: a flexible display comprising a plurality of pixels; a flexible array of convex microlenses; wherein each microlens in the array receives light from a selected number of underlying pixels and projects the received light over a range of viewing angles so as to collectively produce a flexible 3D light field display, and an electronic circuit including at least one processor that controls the pixels of the flexible display. The mobile computing device may further comprise: (a) an x,y-input element that senses a user's touch on the display device in the x and y axes and provides corresponding x,y-input information; or (b) at least one z-input element that senses a bend of the flexible 3D light field display in the z axis and provides corresponding z-input information; or (c) (a) and (b); wherein the electronic circuit includes at least one processor that receives the x,y-input and/or the z-input, and controls the pixels of the flexible display.

Also described herein is a mobile computing device, comprising: a flexible display comprising a plurality of pixels; at least one z-input element that senses a bend of the flexible display in the z axis and provides corresponding z-input information; and an electronic circuit including at least one processor that controls the pixels of the flexible display. The mobile computing device may further comprise: (a) an x,y-input element that senses a user's touch on the display device in the x and y axes and provides corresponding x,y-input information; or (b) a flexible array of convex microlenses; wherein each microlens in the array receives light from a selected number of underlying pixels and projects the received light over a range of viewing angles so as to collectively produce a flexible 3D light field display;

or (c) (a) and (b); wherein the electronic circuit includes at least one processor that receives the x,y-input and/or the z-input, and controls the pixels of the flexible display.

Also described herein is a method for making a display device, comprising: disposing a flexible array of convex microlenses on a flexible display comprising a plurality of pixels; wherein each microlens in the array receives light from a selected number of underlying pixels and projects the received light over a range of viewing angles so as to collectively produce a flexible 3D light field display. The method may include disposing an x,y-input element with the flexible microlens array and the flexible display; wherein the x,y-input element senses a user's touch on the display device in the x and y axes and provides corresponding x,y-input information. The method may include disposing at least one z-input element with the flexible microlens array and the flexible display, wherein the at least one z-input element senses a bend of the flexible 3D light field display in the z axis and provides corresponding z-input information. The method may include disposing at least one z-input element with the flexible microlens array, the flexible display, and the x,y-input element; wherein the at least one z-input element senses a bend of the flexible 3D light field display in the z axis and provides corresponding z-input information.

Also described herein is a method for making a display device, comprising: at least one z-input element with a flexible display comprising a plurality of pixels; wherein the at least one z-input element senses a bend of the flexible display in the z axis and provides corresponding z-input information. The method may include disposing a flexible array of convex microlenses on the flexible display; wherein each microlens in the array receives light from a selected number of underlying pixels and projects the received light over a range of viewing angles so as to collectively produce a flexible 3D light field display. The method may include disposing an x,y-input element with the flexible display; wherein the x,y-input element senses a user's touch on the display device in the x and y axes and provides corresponding x,y-input information.

The method may include implementing a display device embodiment on a mobile computing device comprising an electronic circuit including at least one processor that controls the pixels of the flexible display. The method may comprise: using z-input information to determine a force associated with bending of the flexible display or returning of the flexible display from a bend to substantially planar, and using the force as input to the computing device.

In the embodiments, the flexible display is a flexible OLED (FOLED) display comprising a plurality of pixels, or a variation thereof. In the embodiments, the mobile computing device may comprise a smartphone, a tablet personal computer, a personal digital assistant, a music player, a gaming device, or a combination thereof.

### BRIEF DESCRIPTION OF THE DRAWINGS

For a greater understanding of the invention, and to show more clearly how it may be carried into effect, embodiments will be described, by way of example, with reference to the accompanying drawings, wherein:

FIG. 1 is diagram showing a 3D light field rendering of a tetrahedron, and the inset (top right) shows a 2D rendition, wherein approximately 12 pixel-wide circular blocks render simulated views from an array of different virtual camera positions.

FIG. 2A is a diagram showing a close-up of a section of a display with an array of convex microlenses, according to one embodiment.

FIG. 2B is a diagram showing a side view close-up of a cross-section of a display with pixel blocks and an array of convex microlenses dispersing light rays, according to one embodiment.

FIG. 3 is a photograph showing a flexible light field smartphone prototype with flexible microlens array.

FIG. 4 is a diagram showing an example of a holographic physical gaming application according to an embodiment described herein.

FIG. 5 is a diagram showing an example of a holographic videoconferencing application according to an embodiment described herein.

FIG. 6 is a photograph showing a holographic tetrahedral cursor and target position, with z-slider on the left, used during an experiment described herein.

### DETAILED DESCRIPTION OF EMBODIMENTS

As used herein, the term “mobile computing device” refers to, but is not limited to, a smartphone, a tablet personal computer, a personal digital assistant, a music player, a gaming device, or a combination thereof.

### Flexible 3D Light Field Display

Described herein is a flexible 3D light field display. Embodiments may be prepared as layered structures, as shown in FIGS. 2A and 2B, including a flexible display layer 22 comprising a plurality of pixels (not shown) and a flexible microlens array layer 26 disposed on the display layer 22. The display layer may be any type of flexible display, such as, for example, a flexible organic light emitting diode (FOLED) display. The term FOLED is used herein generally to refer to all such flexible displays, (such as, but not limited to polymer (plastic) organic LED (POLED) displays, and active matrix organic LED (AMOLED) displays). The FOLED may have a resolution of, for example, 1920×1080 pixels (403 dpi). Other display resolutions may also be used, such as, for example, 4K (3840×2160 pixels) and 8K (7680×4320 pixels).

The flexible plastic microlens array includes an array of convex lenses 28. A microlens array may be designed for a given implementation and prepared using any suitable technique such as moulding, micromachining, or 3D-printing. The microlens array may be constructed on a flexible optically clear substrate 27, to facilitate placing on the display. The microlens array may be secured to the display using liquid optically clear adhesive (LOCA) 24. Each convex microlens 28 resembles a droplet, analogous to part of a sphere protruding above the substrate.

The microlens size is inversely related to the pixel density and/or resolution of the display. That is, the microlenses may be smaller as the display resolution/density of pixels increases. The microlcnses may be sized such that each microlens overlies a selected number of pixels (i.e., a “pixel block”, shown at 23 in FIG. 2B, although pixels are not shown) on the display, to provide a sufficiently small angular pitch per pixel block that allows a fused 3D image to be seen by a user at a normal viewing distance from the screen. However, there is a tradeoff between angular pitch and spatial pitch: the smaller the pixel blocks are, the more there are, which provides better spatial resolution but reduces angular resolution. The selected number of pixels in a pixel block may be, for example, 10-100, or 10-500, or 10-1000, although other numbers of pixels, including more pixels, may be selected. Accordingly, each microlens may have a radius corresponding to a sphere radius of about 200 to about 600 μm, and distances between microlens centres may be about 500 to about 1000 μm, although other sizes and distances may also be used. Spacing of the microlenses may be selected to enhance certain effects and/or to minimize other optical effects. For example, spacing of the microlenses may be selected so as to not align with the underlying pixel grid of the display, to minimize Moire effects. In one embodiment, both the X and Y spacing of the microlenses is not an integer multiple of the pixels and the screen is rotated slightly. However, other arrangements may also be used.

The flexible 3D light field display provides a full range of depth cues to a user without the need for additional hardware or 3D glasses, and renders a 3D scene in correct perspective to a multitude of viewing angles. To observe the side of an object in a 3D scene, the user simply moves his/her head as when viewing the side of a real-world object, making use of natural behaviour and previous experiences. This means that no tracking or training is necessary. Since multiple viewing angles are provided, multiple simultaneous users are possible. Thus, in accordance with the embodiments, use of a light field display preserves both motion parallax, critical for viewing objects from different angles, as well as stereoscopy, critical for judging distance, in a way that makes it easier for users to interact with 3D objects, for example, in 3D design tasks.

Flexible 3D Light Field Display with Touch Input

A flexible 3D light field display as described above may be augmented with touch input. The addition of touch input enhances the utility of the flexible 3D light field display when used with, for example, a mobile computing device. Touch input may be implemented by adding a touch-sensitive layer to the flexible 3D light field display. For example, a touch-sensitive layer 25 may be disposed between the display layer 22 and the layer comprising the microlens array 26 (FIG. 2B). In one embodiment, the touch input layer may be implemented with a flexible capacitive multi-touch film. Such a film can be used to sense a user's touch in the x and y axes (also referred to herein as x,y-input). The touch input layer may have a resolution of, for example, 1920×1080 pixels, or otherwise match or approximate the resolution of the microlens array.

Flexible Display with Bend Input

In general, any flexible display may be augmented with bend input as described herein, wherein bending the display provides a further variable for controlling one or more aspects of the display or computing device to which it is connected. For example, bend input may be used to control translation along the z axis (i.e., the axis perpendicular to the display, also referred to herein as z-input). In one embodiment, z-input may be used to resize an object in a graphics editor. In another embodiment, z-input may be used to flip pages in a displayed document. In another embodiment, z-input may be used to control zooming of the display.

A flexible 3D light field display as described above, with or without x,y-input, may be augmented with bend input. The addition of z-input to a flexible 3D light field display as described above enhances the utility of the flexible 3D light field display when used with a mobile computing device.

A flexible 3D light field display with z-input addresses the shortcomings of prior attempts to provide 3D translation on mobile non-flexible platforms using x,y-touch input. Since the third (i.e., z) axis is perpendicular to the touch input plane, no obvious control of z-input is available via x,y-touch. Indeed, prior interaction techniques in this context involve the use of indirect intermediary two-dimensional gestures. While tools exist for bimanual input, such as a thumb slider for performing z operations (referred to as a Z-Slider), these tend to obscure parts of the display space. Instead, the embodiments described herein overcome the limitations of prior approaches by using, e.g., a bimanual combination of dragging and bending as an integral way to control 3D translation. For example, bend input may be performed with the non-dominant hand holding the device, providing an extra input modality that operates in parallel to x,y-touch input by the dominant hand. In one embodiment, the gesture used for bend input is squeezing. For example, this may be implemented by gripping the device in one hand and applying pressure on both sides to create concave or convex curvatures.

When using a device, the user's performance and satisfaction improve when the structure of the task matches the structure of the input control. Integrality of input is defined as the ability to manipulate multiple parameters simultaneously. In the present embodiments, the parameters are x, y, and z translations. The dimensionality and integrality of the input device should thus match the task. In 2D translation, a drag gesture is widely used in mobile devices for absolute x,y-control of a cursor. However, in one embodiment, due to direct mapping of the squeeze gesture to the z axis, users are able to perform z translations using, e.g., the squeeze gesture in a way that is more integral with touch dragging than traditional Z-Sliders.

Aside from providing the capacity for bend input, use of a flexible display form factor provides other benefits. For example, a flexible display is ideally suited for working with 3D objects because it can be molded around the 3D design space to provide up to 180 degree views of an object. In some embodiments, bending the display along the z-axis also provides users with passive haptic force feedback about the z location of the manipulated 3D object.

Bend input may be implemented in a flexible display by disposing one or more bend sensors on or with the display. For example, a bidirectional bend sensor may be disposed on the underside of the FOLED display, or to a flexible substrate that is affixed to the underside of the FOLED display. Alternatively, a bend sensor may be affixed to or integrated with another component of the flexible display, or affixed to or integrated with a flexible component of a computing device with which the flexible display is associated. The one or more bend sensor is connected to electronic circuitry that provides communication of bend sensor values to the device. Other types of electromechanical sensors may be used, such as strain gauges, as will be readily apparent to those of ordinary skill in the art.

In one embodiment a bend sensor is disposed horizontally behind the center of the display. The sensor senses bends in the horizontal dimension (i.e., left-right) when the display is held in landscape orientation. Alternative placements of bend sensors, and combinations of bend sensors variously arranged behind or in relation to the display may facilitate more degrees of freedom of bend input. For example, in one embodiment, a bend sensor is disposed diagonally from a corner of the display towards the center, to provide input using a “dog ear” gesture (i.e., bending the corner of the display).

### Flexible Mobile Computing Device

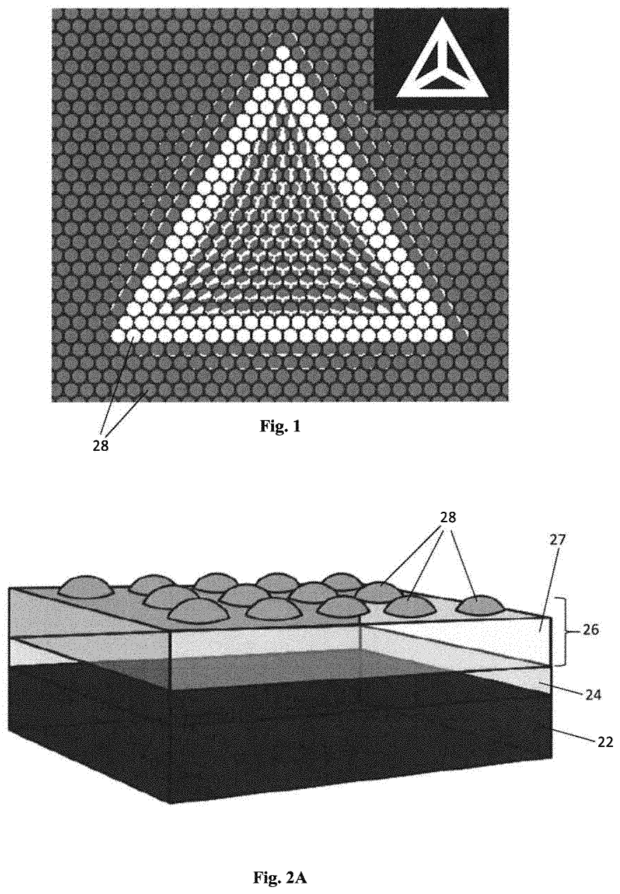

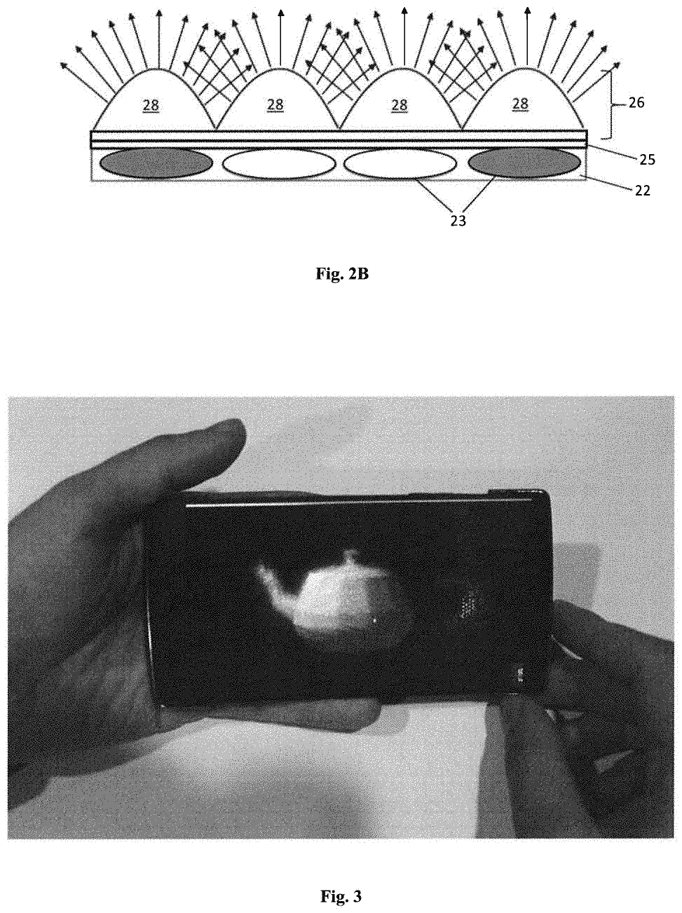

Described herein is a flexible mobile computing device including a flexible 3D lightfield display as described above. In particular, a prototype based on a smartphone (FIG. 1) is described. However, it will be appreciated that flexible mobile computing devices other than smartphones may be constructed based on the concepts described here.

The smartphone prototype had five main layers: 1) a microlens array, 2) a flexible touch input layer, 3) a high resolution flexible OLED; 4) a bend sensor, and 5) rigid electronics and battery. A rendering algorithm was developed and was executed by the smartphone's GPU. These are described in detail below.

### 1. Microlens Array

A flexible plastic microlens array was custom-designed and 3D-printed. The microlens array had 16,640 half-dome shaped droplets for lenses. The droplets were 3D-printed on a flexible optically clear substrate 500 μm in thickness. The droplets were laid out in a 160×104 hexagonal matrix with the distance between droplet centres at 750 μm. Each microlens corresponded to an approximately 12 pixel-wide substantially circular area of the underlying FOLED display; i.e., a pixel block of about 80 pixels. The array was hexagonal to maximize pixel utilization, however, other array geometries may be used. Each droplet corresponded to a sphere of a radius of 400 μm “submerged” in the substrate, so that the top of each droplet was 175 μm above the substrate. The droplets were surrounded by a black circular mask printed onto the substrate. The mask was used to limit the bleed from unused pixels, effectively separating light field pixel blocks from one another. The microlens array allowed for a sufficiently small angular pitch per pixel block to see a fused 3D image at a normal viewing distance from the screen. In this embodiment, the spacing of the microlenses was chosen to not align with the underlying pixel grid to minimize Moire effects. As a result, both the X and Y spacing of the microlenses is not an integer multiple of the pixels and the screen is rotated slightly. However, other arrangements may also be used. The microlens array was attached to the touch input layer using liquid optically clear adhesive (LOCA).

FIG. 1 is diagram showing a 3D light field rendering of a tetrahedron as produced by the flexible 3D light field display (the inset (top right) shows a 2D rendition), wherein 12 pixel-wide circular blocks rendered simulated views from different angles.

### 2. Touch Input Layer

The touch input layer was implemented with a flexible capacitive multi-touch film (LG Display Co., Ltd.) that senses x,y-touch with a resolution of 1920×1080 pixels.

### 3. Display Layer

The display layer was implemented with a 121×68 mm FOLED display (LG Display Co., Ltd.) with a display resolution of 1920×1080 pixels (403 dpi).

### 4. Bend Sensor Layer

A bidirectional 2″ bend sensor (Flexpoint Sensor Systems, Inc.) placed horizontally behind the center of the display. The sensor senses bends in the horizontal dimension (i.e., left-right) when the smartphone is held in landscape orientation. The bend sensor was connected to a communications chip (RFduino) with Bluetooth hardware. RFduino Library 2.3.1 allows communication of bend sensor values to the smartphone board over a Bluetooth connection.

### 5. Circuitry and Battery Layer

This layer included a 66×50 mm Android circuit board with a 1.5 GHz Qualcomm Snapdragon 810 processor and 2 GB of memory. The board was running Android 5.1 and included an Adreno 430 GPU supporting OpenGL 3.1. The circuit board was placed such that it formed a rigid handle on the left back of the prototype. The handle allowed a user to comfortably squeeze the device with one hand. A custom designed 1400 mAh flexible array of batteries was placed in the center back of the device such that it could deform with the display.

### Rendering Algorithm

Whereas images suitable for a light field display may be captured using an array of cameras or a light field camera, the content in the present embodiments is typically generated as 3D graphics. This requires an alternative capture method such as ray tracing. Ray tracing is very computationally expensive on a mobile device such as a smartphone. Since the computation depends on the number of pixels, limiting the resolution to 1920×1080 pixels allowed for real-time rendering of simple polygon models and 3D interactive animations in this embodiment.

As shown in the diagram of FIG. 2B, each microlens 28 in the array 26 redistributes light emanating from the FOLED pixels into multiple directions, indicated by the arrows. This allows modulation of the light output not only at each microlens position but also with respect to the viewing angle of that position. In the smartphone prototype, each pixel block rendered on the light field display consisted of an 80 pixel rendering of the entire scene from a particular virtual camera position along the x,y-plane. The field of view of each virtual camera was fixed by the physical properties of the microlenses to approximately 35 degrees. The scene was rendered using a ray-tracing algorithm implemented on the GPU of the phone. A custom OpenGL fragment shader was implemented in GLSL ES 3.0 for real-time rendering by the phone's on-board graphics chip. The scene itself was managed by Unity 5.1.2, which was also used to detect touch input.

Embodiments are further described by way of the following non-limiting examples.

### EXAMPLES

### Application Scenarios

A number of application scenarios were developed and implemented to examine and highlight functionality of the embodiments. In the examples, the term “hologram” refers to the 3D image rendered in the flexible light field display.

### Holographic Editing of a 3D Print Model

This application demonstrates the use of bend gestures for Z-input to facilitate the editing of 3D models, for example, for 3D printing tasks. Here, x,y-positioning with the touch screen is used for moving elements of 3D models around the 2D space. Exerting pressure in the middle of the screen, by squeezing the screen (optionally with the non-dominant hand), moves the selected element in the z dimension. By using inertial measurement unit (IMU) data, x,y,z orientation of elements can be facilitated. Having IMU data affect the orientation of selected objects only when a finger is touching the touchscreen allows viewing of the model from any angle without spurious orientational input. By bending the display into a concave shape, multiple users can examine a 3D model simultaneously from different points of view. The application was developed using the Unity3D platform (Unity Technologies, San Francisco, USA).

### Holographic Physical Gaming

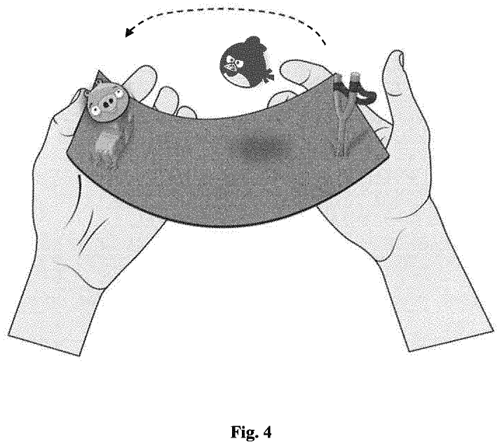

This application is a holographic game (FIG. 4). The bend sensors and IMU in the device allow for the device to sense its orientation and shape. This allows for gaming experiences that are truly imbued with physics: 3D game elements are presented as an interactive hologram, and deformations of the display can be used as a physical, passive haptic input device. To demonstrate this, we chose to develop a version of the Angry Birds™ game (https://play.google.com/store/apps/details?id=com.rovio.angrybirds&hl=en) with limited functionality, in the Unity3D platform. Rather than using touch input, users bend the side of the display to pull the elastic rubber band that propels the bird. To release the bird, the user releases the side of the display. The velocity with which this occurs is sensed by the bend sensor and conveyed to a physics engine in the gaming application, sending the bird across the display with the corresponding velocity. This provides the user with passive haptic feedback representing the tension in the rubber band.

Users are able to become proficient at the game (and other applications with similar functionality) because the device lets the user see and feel the physics of the gaming action with full realism. As the right side of the display is pulled to release the bird, the user feels the display give way, representing the passive haptics of pulling a rubber band. As the user releases the side of the display, the device measures the force with which the bent device returns to a flat (i.e., planar) or substantially flat shape, which serves as input to the game to determine the acceleration or velocity of the Angry Bird. Upon release, the Angry Bird is sent flying towards its target on the other side of the display with the force of the rebound. As the bird flies it pops out of the screen in 3D, and the user can observe it fly from various angles by rotating the display. This allows the user to estimate very precisely how to hit the target.

### Multiview Holographic Videoconferencing

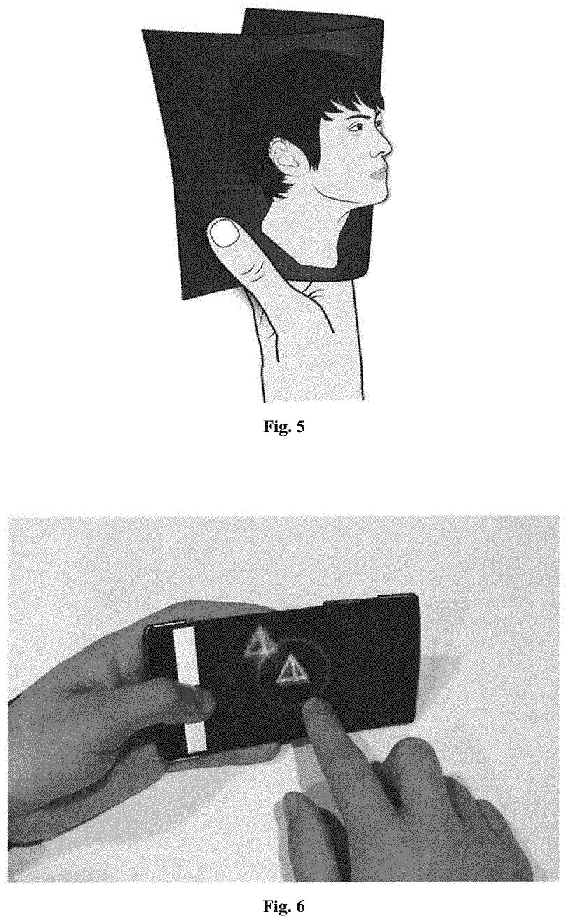

The third application was a 3D holographic video conferencing system. When the light field display is augmented with 3D depth camera(s) such as Project Tango (https://www.google.com/atap/project-tango/), or a transparent flexible light field image sensor (ISORG and Plastic Logic co-develop the world's first image sensor on plastic. http://www.isorg.fr/actu/4/isorg-and-plasticlogic-co-develop-the-world-s-first-image-sensor-on-plastic_149.htm), it can capture 3D models of real world objects and people. This allows the device to convey holographic video images viewable from any angle. To implement the system, RGB and depth images were sent from a Kinect 2.0 capturing a remote user over a network as uncompressed video images. These images were used to compute a real-time coloured point cloud in Unity3D. This point cloud was raytraced for display on the device. Users may look around the hologram of the remote user by bending the screen into a concave shape as shown in FIG. 5, while rotating the device. This presents multiple local users with different viewpoints around the 3D video in stereoscopy and with motion parallax.

For example, in a 3D video-conference, an image of a person is presented on the screen in 3D. The user can bend the device in a concave shape, thus increasing the visible resolution of the lens array, creating an immersive 3D experience that makes the user feel closer to the person in the image. The user can bend the device in a convex shape, and rotate it, allowing another viewer to see a frontal view while the user sees the image from the side.

### User Study

Two experiments were conducted to evaluate the device prototype. The first experiment evaluated the effect of motion parallax versus stereoscopy-only depth cues on a bimanual 3D docking task in which a target was moved using a vertical touch slider (Z-Slider). The second experiment compared the efficiency and integrality of bend gestures with that of using a Z-Slider for z translations.

### Task

In both experiments, the task was based on a docking experiment designed by Zhai (Zhai, S., 1995, “Human Performance in Six Degree of Freedom Input Control”). Subjects were asked to touch a 3D tetrahedron-shaped cursor, which was always placed in the center of the screen, and align it in three dimensions to the position of a 3D target object of the same size and shape. FIG. 6 shows a 3D rendition of a sample cursor and target (a regular tetrahedron with edge length of 17 mm), as used in the experiment.

### Trials and Target Positions

In both experiments, during a trial, the 3D target was randomly placed in one of eight x,y-positions distributed across the screen, and 3 positions distributed along the z axis, yielding 24 possible target positions. Each target position was repeated three times, yielding a total of 72 measures per trial.

### Experimental Design

Within-subject repeated measures designs were used for both experiments, and each subject performed both experiments. The order of presentation of experiments and conditions was fully counterbalanced. Presentation of conditions was performed by a C# script running on a Windows 8 PC, which communicated with Unity 3D software on the phone via a WiFi network.

### Experiment 1: Effect of Depth Cues on 3D Docking Task

The factor in the first experiment was the presence of depth cues: motion-parallax with stereoscopy vs. stereoscopy-only. The motion parallax+stereoscopy condition presented the image as given by the lightfield display. Users could observe motion parallax by either moving their head relative to the display or moving the display relative to their head. In the stereoscopy-only condition a single pair of stereo images was rendered. This was done by only displaying the perspectives that would be seen by a participant when his/her head was positioned straight above the center of the display at a distance of about 30 cm. In the stereoscopy-only condition, subjects were therefore asked to position and maintain their head position about 30 cm above the center of the display. In both conditions, participants performed z translations using a z-slider widget operated by the thumb of the non-dominant hand (see FIG. 6). The display was held by that same hand in landscape orientation. The x,y-position of the cursor was operated via touch input by the index finger of the dominant hand.

### Experiment 2: Effect of Bend Input on 3D Docking Task

The factor in the second experiment was Z-Input Method, with two conditions: bend gestures vs. use of a Z-Slider. In both these conditions, participants experienced the lightfield with full motion parallax and stereoscopy. In both conditions, the display was held by the non-dominant hand, in landscape orientation, and the cursor was operated by the index finger of the dominant hand. In the Z-Slider condition, users performed z translations of the cursor using a Z-Slider on the left side of the display (see FIG. 6), operated by the thumb of the non-dominant hand. In the bend condition, users performed z translations of the cursor via a squeeze gesture performed using their non-dominant hand.

### Dependent Variables

In both experiments, measures included time to complete task (Movement time), distance to target upon docking, and integrality of movement in the x,y- and z dimensions. Movement time measurements started when the participant touched the cursor, until the participant released the touchscreen. Distance to target was measured as the mean Euclidian distance between the 3D cursor and 3D target locations upon release of the touchscreen by the participant. To measure integrality, the 3D cursor position was collected at 80 ms intervals throughout every trial. Integrality was calculated based on a method by Masliah and Milgram (Masliah, M., et al., 2000, “Measuring the allocation of control in a 6 degree-of-freedom docking experiment”, In Proceedings of the SIGCHI conference on Human Factors in Computing Systems (CHI '00), ACM, New York, N.Y., USA, pp. 25-32). Generally, for each interval, the minimum of the x,y- and z distance reductions to target, in mm, were summed across each trial, resulting in an integrality measure for each trial.

### Results

For the sake of brevity, a detailed report of the results and analysis is omitted. Twelve participants received appropriate training with the device prior to participating in the experiments. The experiments demonstrated that the use of both motion parallax via a lightfield and stereoscopy via a flexible display improved the accuracy and integrality of movement towards the target, while bend input significantly improved movement time. Thus, it is concluded that the prototype significantly improved overall user performance in the 3D docking task.

### EQUIVALENTS

While the invention has been described with respect to illustrative embodiments thereof, it will be understood that various changes may be made to the embodiments without departing from the scope of the invention. Accordingly, the described embodiments are to be considered merely exemplary and the invention is not to be limited thereby.

1. A display device, comprising:
a flexible display comprising a plurality of pixels;
a flexible array of convex microlenses disposed on the flexible display; and
at least one z-input element;
wherein each microlens in the array receives light from a pixel block comprising at least ten underlying pixels arranged in x and y directions and disperses the received light into multiple directions over a range of x and y viewing angles so as to collectively produce a flexible 3D light field display with motion parallax and stereoscopy;
wherein the at least one z-input element senses a bend of the flexible 3D light field display in a z axis and provides corresponding z-input information.

2. The display device of claim 1, comprising:
an x,y-input element;
wherein the x,y-input element senses a user's touch on the display device in the x and y axes and provides corresponding x,y-input information.

3. The display device of claim 2, wherein the x,y-input element comprises a flexible capacitive multi-touch film.

4. The display device of claim 3, wherein the flexible capacitive multi-touch film is disposed between the flexible display and the flexible array of convex microlenses.

5. The display device of claim 2, wherein one or more properties of a light field rendered on the flexible 3D light field display is modulated by touching and/or bending the flexible 3D light field display.

6. The display device of claim 1, wherein the at least one z-input element comprises a bend sensor.

7. The display device of claim 1, wherein the flexible display is a flexible OLED (FOLED) display.

8. A mobile computing device, comprising:
a flexible display comprising a plurality of pixels;
a flexible array of convex microlenses disposed on the flexible display; and
at least one z-input element;
wherein each microlens in the array receives light from a pixel block comprising at least ten underlying pixels arranged in x and y directions and disperses the received light into multiple directions over a range of x and y viewing angles so as to collectively produce a flexible 3D light field display with motion parallax and stereoscopy;
wherein the at least one z-input element senses a bend of the flexible 3D light field display in a z axis and provides corresponding z-input information; and
an electronic circuit including at least one processor that controls the pixels of the flexible display.

9. The mobile computing device of claim 8, comprising:
an x,y-input element that senses a user's touch on the display device in the x and y axes and provides corresponding x,y-input information;
wherein the electronic circuit includes at least one processor that receives the x,y-input and/or the z-input, and controls the pixels of the flexible display.

10. The mobile computing device of claim 8, wherein the flexible display is a flexible OLED (FOLED) display.

11. The mobile computing device of claim 8, comprising a smartphone, a tablet personal computer, a personal digital assistant, a music player, a gaming device, or a combination thereof.

12. A method for making a display device, comprising:
disposing a flexible array of convex microlenses on a flexible display comprising a plurality of pixels;
disposing at least one z-input element with the flexible display;
wherein each microlens in the array receives light from a pixel block comprising at least ten underlying pixels arranged in x and y directions and disperses the received light into multiple directions over a range of x and y viewing angles so as to collectively produce a flexible 3D light field display with motion parallax and stereoscopy;
wherein the at least one z-input element senses a bend of the flexible 3D light field display in a z axis and provides corresponding z-input information.

13. The method of claim 12, comprising:
disposing an x,y-input element with the flexible microlens array and the flexible display;
wherein the x,y-input element senses a user's touch on the display device in the x and y axes and provides corresponding x,y-input information.

14. The method of claim 13, wherein touching and/or bending the flexible 3D light field display modulates one or more properties ofa light field rendered on the flexible 3D light field display.

15. The method of claim 12, comprising disposing a flexible FOLED display comprising a plurality of pixels.

16. The method of 12, implemented on a mobile computing device comprising an electronic circuit including at least one processor that controls the pixels of the flexible display.

17. The method of claim 16, comprising:
disposing an x,y-input element that senses a user's touch on the display device in the x and y axes and provides corresponding x,y-input information;
wherein the electronic circuit includes at least one processor that receives the x,y-input and/or the z-input, and controls the pixels of the flexible display.

18. The method of claim 17, comprising:
using the z-input information to determine a force associated with bending of the flexible display or returning of the flexible display from a bend to substantially planar; and
using the force as input to the computing device.

19. The method of claim 16, wherein the mobile computing device comprises a smartphone, a tablet personal computer, a personal digital assistant, a music player, a gaming device, or a combination thereof.
